(19) United States
(12) Patent Application Publication
(10) Pub. No.: US 2025/0181792 A1
(43) Pub. Date: Jun. 5, 2025

(54) MODELING, CALIBRATION METHOD AND DEVICE FOR NONLINEAR SYSTEM IN COMPUTATIONAL LITHOGRAPHY

(71) Applicant: Wuhan Yuwei Optical Software Co., Ltd., Hubei (CN)

(72) Inventors: Haiqing Wei, Hubei (CN); Song Zhang, Hubei (CN)

(73) Assignee: Wuhan Yuwei Optical Software Co., Ltd., Hubei (CN)

(21) Appl. No.: 18/434,635

(22) Filed: Feb. 6, 2024

(30) Foreign Application Priority Data
Dec. 4, 2023 (CN) 202311642433.2

(51) Int. Cl. G03F 7/00

(52) U.S. Cl. CPC G06F 30/20

(57) ABSTRACT

Disclosed is a modeling and calibration method and device for a nonlinear system in computational lithography, which belongs to the field of computational lithography modeling. The present disclosure provides a new nonlinear modeling idea of cascade and combination of second-order Wiener systems. Through the combination of modeling modules within the same stage, and cascade, parallel or mixed connection between different modules, multi-stages are constructed to solve simulation problems of second-order characteristics and above in nonlinear systems. The universal advantage of second-order Wiener systems in describing nonlinear continuous systems and processes is emphasized and utilized. The cascade combination prevents increase of complexity while ensuring the ability to describe high-order characteristics of the system.

### CROSS-REFERENCE TO RELATED APPLICATIONS

This application claims the priority benefit of China application no. 202311642433.2 filed on Dec. 4, 2023. The entirety of the above-mentioned patent application is hereby incorporated by reference herein and made a part of this specification.

### BACKGROUND

### Technical Field

The disclosure belongs to the field of computational lithography modeling, and more specifically, relates to a modeling and calibration method and device for a nonlinear system.

### Description of Related Art

As critical dimension gradually reduces, optical proximity correction (OPC) and source mask optimization (SMO) have become one of the most important and common resolution enhancement technologies. Such optimization technology includes a lithography imaging model and an inverse optimization process. The inverse optimization process requires repeated iterations, and each iteration requires invoking the lithography imaging model. Therefore, an efficient and accurate lithography imaging model is the key to ensure this type of optimization technology. Especially, there is a large scale and high frequency lithography imaging calculation challenge for the full-chip OPC or SMO required for large-scale IC manufacturing at industrial sites.

The lithography imaging system is a complex physical process, involving the interaction between light and different material, as well as the physical and chemical reactions of photoresist during exposure and development. Inevitably, there are many nonlinear processes involved. Now there are relatively mature solutions for eigen decomposition or kernel function decomposition operation of the transmission cross coefficient (TCC). However, for other stages and reaction effects in the lithography process, staged linear or bilinear approximation methods have become less suitable as critical dimension decreases. In particular, efficient and accurate modeling methods are urgently required for nonlinear processes such as three-dimensional mask effects and photoresist modeling.

### SUMMARY

In view of the shortcomings of the existing technology, the purpose of the present disclosure is to provide a modeling and calibration method and device for nonlinear system in computational lithography, aiming to improve the efficiency and accuracy of nonlinear systems modeling in computational lithography.

To achieve the above purposes, in the first aspect, the present disclosure provides a modeling method for a nonlinear system in computational lithography, including:
calculating a corresponding modeling module according to a kernel function group of each modeling module in the network architecture of a computational lithography system until all modeling modules are calculated, and obtaining the overall network model of the computational lithography system, wherein
the network architecture is composed of multiple identical or different stages, each stage is composed of multiple identical or different modeling modules, and the entire network architecture includes at least one second-order Wiener module;
a number of stages of the network architecture, the connection methods between different stages, a number and combination of modeling modules in each stage, and the kernel function group of each modeling module, are all set according to the characteristics of the nonlinear system.

Preferably, for each second-order Wiener module, the coefficient matrix of the second-order Wiener product function are eigen decomposed, the eigenmatrix and the original kernel function are merged, summed in advance and stored as a new kernel function, and the eigenvalues are used as variable coefficients.

Preferably, the types of the modeling modules include: linear Wiener modules, second-order Wiener modules and Wiener-Padé modules; the combination of the modelling modules include: addition, subtraction or construction branches; the connection methods of the modeling modules include: cascade, parallel or mixed connection.

Preferably, for each Wiener-Padé modules, the product functions and sum functions of a numerator and a denominator are constructed respectively, and further constructed by point-by-point division.

Preferably, the calculation of the new kernel function is specifically as follows:
(1) Performing eigen decomposition on the coefficient matrix of the second-order term in the Wiener system to obtain a matrix of eigenvector U;
(2) Calculating the new Wiener kernel function G=U*K, wherein K represents an original Wiener kernel function.

Preferably, the new Wiener kernel function is reduced in order to obtain the reduced second-order term T_{qua}=Σᵢλᵢ(I⊗Gᵢ)²; wherein λ is a new Wiener coefficient of the second-order term, the subscript i represents the i-th new Wiener kernel function, and/represents the input signal.

It should be noted that the present disclosure preferably performs order reduction in the above manner, thereby reducing the computational complexity and significantly improving the computational efficiency.

Preferably, the method further includes: after performing parameter calibration of the overall network model, verifying the overall network model of the computational lithography system to determine whether the model meets the modeling requirements; if the model meets the modeling requirements, output the overall network model; otherwise, adjust and remodel the network architecture.

Preferably, the adjustment method is at least one of the following: 1) adding one stage of cascade connection to expand the depth of the network; 2) internally adjusting one of the stages to a form of two or more Wiener sub-modules connected in parallel; 3) adjusting an inner combination method of one of the stages.

Preferably, the nonlinear system in computational lithography is a three-dimensional thick mask diffraction system or a photoresist system during exposure and development.

Preferably, if the system is the three-dimensional thick mask light scattering system, the criterion for meeting the modeling requirements is: the difference between the diffraction light field output by the model and the reference diffraction light field is less than the preset value; if the system is the photoresist reaction system, the criterion for meeting the modeling requirements is: the difference between the critical dimensions or other profile data output by the calibrated resist model and the reference data is less than the specified value or a preset value.

In order to achieve the above purpose, in a second aspect, the present disclosure provides a calibration method for the nonlinear system. The calibration method includes:
T1: receiving and calculating the overall network model of the lithography system, which is modeled using the method described in the first aspect of the disclosure;
T2: receiving calibration data samples of the computational lithography system, wherein the calibration data sample includes calculating the input data of the first stage of the system and the actual output value of a sub-module of the last stage;
T3: extracting the Wiener model of a sub-module of the first-stage, convolving with the Wiener kernel function and storing the Wiener model; fixing sub-modules of the subsequent stage as identity or simple linear operators, and initializing the current stage to the second stage;
T4: extracting the Wiener model of a sub-module of the current stage, using the output result of sub-module of the previous stage as the input of this stage, convolving with the Wiener kernel function and storing the model; in the meantime, fixing the sub-module of the subsequent stage to be identity or simple linear operators;
T5: initializing the Wiener coefficients that need to be calibrated;
T6: calculating the model output and obtaining the estimated output of the sub-module of the last stage;
T7: comparing the estimated output of sub-module of the last stage with the actual output of sub-module of the last stage to determine whether a calibration stop condition for the sub-module of the current stage is met. If the calibration stop condition is not met, move to step T8; if the calibration stop condition is met, move to step T9;
T8: optimizing and updating Wiener coefficients;
T9: determining whether the calibration of the sub-modules of all stages have been completed; if not, that is, the current stage is not the last stage, move to step T10; if yes, move to step T11;
T10: updating the next stage to the current stage according to the connection sequence and move to step T4;
T11: completing the model calibration and outputting the Wiener coefficients of each stage.

Preferably, for the square operation in the second-order term after the order reduction, upsampling is first performed during calculation, and the square operation is performed afterwards;

the upsampling comprises: performing fast Fourier transform on the input signal to be squared into the frequency domain; extending the value interval to at least twice the original interval to each side in the spatial frequency domain, filling in the continuation area with zeros, and then using the inverse Fourier transform to return to the original domain.

It should be noted that the present disclosure preferably calculates the square term of the second-order term in the above manner, which may completely avoid the occurrence of spectrum aliasing.

In order to achieve the above purpose, in a third aspect, the present disclosure provides a modeling and calibration device for the nonlinear system in computational lithography, including: a processor and a memory; wherein the memory is configured to store computer execution instructions; the processor is configured to execute the computer execution instructions, so that the method described in the first aspect is executed, or the method described in the second aspect is executed.

Generally speaking, compared with the related art, the above technical solution conceived by the present disclosure has the following advantageous effects:

The present disclosure provides a modeling and calibration method and device for a nonlinear system, and provides a new nonlinear modeling idea of cascade combination of second-order Wiener system. Multi-stages are constructed through the combination of modeling modules in each stage and also the combination of different stages, including cascade, and parallel or mixed connection, thereby solving the modeling problems of second-order and above characteristics in nonlinear systems. The universal advantage of second-order Wiener systems in describing nonlinear continuous systems and processes is emphasized and utilized. The cascade combination makes it possible to prevent increase of complexity while ensuring the ability to describe high-order characteristics of the system.

### BRIEF DESCRIPTION OF THE DRAWINGS

FIG. 1 is a flow chart of a modeling method for a nonlinear system in computational lithography provided by the present disclosure.

FIG. 2 is a specific implementation flow chart for establishing a photoresist model during exposure and development provided by an embodiment of the present disclosure.

### DESCRIPTION OF THE EMBODIMENTS

In order to make the purpose, technical solutions and advantages of the present disclosure more clear, the present disclosure will be further described in detail below with reference to the accompanying drawings and embodiments. It should be understood that the specific embodiments described here are only configured to explain the present disclosure and are not intended to limit the present disclosure.

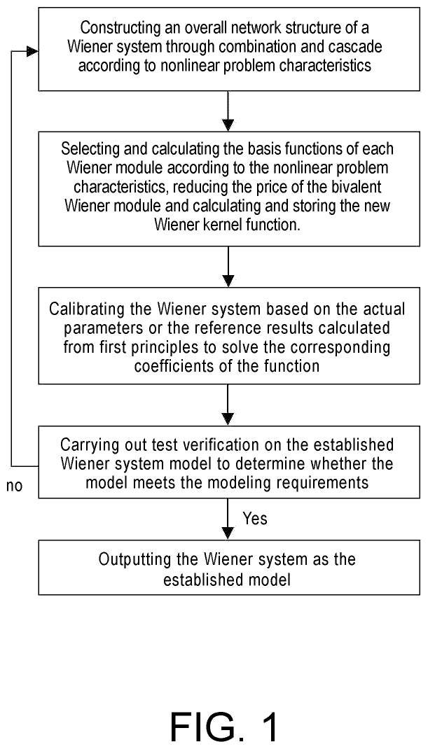

As shown in FIG. 1, the present disclosure provides a modeling method for a nonlinear system, including:
calculating a corresponding modeling module according to a kernel function group of each modeling module in the network architecture of a computational lithography system until all modeling modules are calculated, and obtaining the overall network model of the computational lithography system, wherein
the network architecture is composed of multiple identical or different stages, each stage is composed of multiple identical or different modeling modules, and the entire network architecture includes at least one second-order Wiener module;
the number of stages of the network architecture, the connection methods between different stages, the number and combination of modeling modules in each stage, and the kernel function group of each modeling module, are all set according to the characteristics of the nonlinear system in computational lithography.

According to the Theorem of Wiener representability, any nonlocal and nonlinear function may be arbitrarily approximated by a cascade of convolutions and pointwise polynomial multiplications. Given an input signal I, any continuous nonlinear system T may be approximated as a Wiener system: the input signal is convolved with multiple Wiener kernel functions to obtain multiple convolution results, whose multiple Wiener kernel functions form an orthonormal basis, multiple convolution results are mixed and multiplied point by point to obtain multiple Wiener products. Multiple Wiener products are weighted by Wiener coefficients and summed:

T[I]=Const.+Σᵢaᵢ(I⊗Kᵢ)+Σ_{i,j}aᵢⱼ(I⊗Kᵢ)·(I⊗Kᵢ)+ . . .

When a Wiener system is truncated to a second-order Wiener product, the system is called a second-order Wiener system.

Accordingly, the disclosure provides a method of efficient nonlinear modeling by cascading and compositing quadratic Wiener systems, in which each Wiener sub-module has the characteristics of the above formula and is truncated to the second-order Wiener product. Without loss of generality, any second-order Wiener system may always be characterized as a symmetric quadratic form, in which there is aᵢⱼ=aⱼᵢ for any pair of subscripts (i, j).

Similar to the multi-layer convolutional neural network structure, the cascaded multi-stage second-order Wiener system may approximately characterize any continuous nonlinear system. There are many convolutions and point-wise multiplication operations for the Wiener model and allowing various combinations and cascades. It should be noted that if only the linear Wiener model is adopted, even if the model is cascaded, the model cannot characterize the nonlinear system. The second-order Wiener model may be configured to characterize nonlinear characteristics in nonlinear systems; cascading multiple second-order Wiener module may solve the characterization of higher-order nonlinear systems. From the perspective of mathematical characterization and engineering efficiency requirements, it is necessary to use and only use the second-order Wiener model. The computational complexity of third-order and above polynomials is too high, that is, the computational complexity of n-order polynomials is O(Lⁿ), and therefore the computational cost is too high. The calculation of second-order Wiener polynomials may reduce the computational complexity to O(L), and cascading multiple second-order Wiener modules may characterize higher-order systems. Therefore, by cascading multiple second-order Wiener modules to construct a deep Wiener network structure, each module may be calculated efficiently, and the cascade of multiple modules may be completed quickly, thus enabling efficient modeling and calculation of high-order nonlinear systems.

Similar to the construction of deep neural networks, in the process of constructing cascades, the cascaded modules are not limited to second-order Wiener models. Simpler linear Wiener modules or other low-order functions may be cascaded to represent nonlinear systems while reducing the computational complexity. The second-order Wiener system may be combined with other nonlinear functions, such as the rational functions of the Wiener-Padé module, so as to further improve the modeling capabilities of nonlinear systems.

Preferably, the types of modeling modules include: linear Wiener modules, second-order Wiener modules and Wiener-Padé modules; the combination methods include: addition, subtraction or construction branches; the connection methods include: cascade, parallel or mixed connection.

It is worth noting that one of the combination methods is to add two second-order Wiener modules. The two modules may adopt two different sets of kernel functions, such as but not limited to, setting the kernel function of one sub module to adopt a relatively small Gaussian diffusion coefficient σ and adopt a relatively large σ for another sub module when modeling the resist model. Such setting sometimes produces a certain redundancy, but the setting will be extremely efficient in fitting calibration.

Based on the characteristics of the nonlinear problem, a set of kernel functions is selected for each modeling module.

For each second-order Wiener module, the coefficient matrix of the second-order Wiener product function are eigen decomposed, the eigenmatrix and the original kernel function are merged, summed in advance and stored as a new kernel function, and the eigenvalues are used as variable coefficients.

Preferably, the calculation of the new kernel function is specifically as follows:
(1) Performing eigen decomposition on the coefficient matrix of the second-order term in the Wiener system to obtain the matrix of the eigenvector U;
(2) Calculating the new Wiener kernel function G=U*K, wherein K represents an original Wiener kernel function.

Preferably, the new Wiener kernel function is reduced in order to obtain the reduced second-order term T_{qua}=Σᵢλᵢ(I⊗Gᵢ)²; wherein λ is a new Wiener coefficient of the second-order term, the subscript i represents the i-th new Wiener kernel function, and I represents the input signal.

When calculating the second-order Wiener model, the model may be reduced to reduce the computational complexity and significantly improve the computational efficiency. When calculating the first-order terms, the Wiener kernel function may be summed in advance and stored;

when calculating the second-order terms, the coefficients may be eigen decomposed, the eigenmatrix and the original kernel function K may be merged, and be summed and stored in advance as the new kernel function, wherein eigenvalues serve as variable coefficients:

$$T [ I ] = Const . + I ⊗ [ {\sum }_{i} {a}_{i} {K}_{i} ] + {\sum }_{i} {{λ}_{i} ( I ⊗ {G}_{i} )}^{2}$$

For each Wiener-Padé modules, the product functions and sum functions of a numerator and a denominator are constructed respectively, and further constructed by point-by-point division.

The Wiener-Padé module adopts point-wise division of Wiener polynomial for model construction. If the order of the denominator Order_{de} is greater than or equal to the order of the numerator Orderₙᵤ, that is, Order_{de}≥Orderₙᵤ, then when the input of the function approaches infinity, the function output approaches 0 or a certain fixed value constant, that is, the system module T is bounded. This response characteristic is consistent with the response characteristics of photoresist reaction and many other physical processes, and may be well applied in system modeling of this type of response characteristics. When only polynomials of convolution and point-wise multiplication are adopted, it is not possible to meet this kind of response characteristic.

Preferably, the method further includes: after performing parameter calibration of the overall network model, verifying the overall network model of the computational lithography system to determine whether the model meets the modeling requirements; if the model meets the modeling requirements, output the overall network model; otherwise, adjust and remodel the network architecture.

Preferably, the adjustment method is at least one of the following: 1) adding one stage of cascade connection to expand the depth of the network; 2) internally adjusting one of the stages to a form of two or more Wiener sub-modules connected in parallel; 3) adjusting an inner combination method of one of the stages.

Preferably, the nonlinear system in computational lithography is a three-dimensional thick mask diffraction system or a photoresist reaction system during exposure and development.

Preferably, if the system is a three-dimensional thick mask diffraction system, the criterion for meeting the modeling requirements is: the difference between the diffraction light field output by the model and the reference diffraction light field is less than the preset value; if the system is a photoresist reaction system, the criterion for meeting the modeling requirements is: the difference between the simulation critical dimensions of photoresist or the other photoresist profile data output by the calibrated model and the reference data is less than the specified value or preset value.

The present disclosure provides a calibration method for a nonlinear system in computational lithography. The calibration method includes:
T1: receiving and calculating the overall network model of the lithography system, which is modeled using the method described above;
T2: receiving calibration data samples of the computational lithography system, wherein the calibration data sample includes calculating the input data of the first stage of the lithography system and the actual output value of the sub-module of the last stage;
wherein the calibration data sample may adopt, but is not limited to, system output parameter values obtained through actual experiments or through simulation output parameter values based on first principles;
T3: extracting the Wiener model of a sub-module of the first stage, convolving with the Wiener kernel function and storing the Wiener model; fixing sub-modules of the subsequent stage as identity or simple linear operators, and initializing the current stage to the second stage;
T4: extracting the Wiener model of the sub-module of the current stage, using the output result of sub-module of the previous stage as the input of this stage, convolving with the Wiener kernel function and storing the model; fixing the sub-module of the subsequent stage to be identity or simple linear operators;
T5: initializing the Wiener coefficients that need to be calibrated;
T6: calculating the model output and obtaining the estimated output of the sub-module of the last stage;
T7: comparing the estimated output of sub-module of the last stage with the actual output of sub-module of the last stage to determine whether a calibration stop condition for the sub-module of the current stage is met. If the calibration stop condition is not met, move to step T8; if the calibration stop condition is met, move to step T9;
T8: optimizing and updating Wiener coefficients;
T9: determining whether the calibration of the sub-modules of all stages has been completed; if not, that is, the current stage is not the last stage, move to step T10; if yes, move to step T11;
T10: updating the current stage to the sub-module of the next stage according to the connection sequence and move to step T4;
T11: completing the model calibration and outputting the Wiener coefficients of each stage.

The calibration process is a process of solving each coefficient, and may adopt but is not limited to various second-order optimization solving algorithms.

Preferably, for the square operation in the second-order term after order the reduction, upsampling is first performed during calculation, and the square operation is performed afterwards. The specific implementation method of the upsampling is: performing fast Fourier transform on the input signal to be squared into the frequency domain; extending the value interval to at least twice the original interval for each side in the spatial frequency domain, filling in the continuation area with zeros, and then using the inverse Fourier transform to return to the original domain.

The disclosure provides a modeling and calibration device for a nonlinear system in computational lithography, and the device including: a processor and a memory; the memory is configured to store computer execution instructions; the processor is configured to execute the computer execution instructions so that the above modeling method is executed, or the above calibration method is executed.

### Embodiment 1

The disclosure is suitable for modeling nonlinear systems or nonlinear processes, and may be used for a complete nonlinear system or a certain nonlinear stage or process therein.

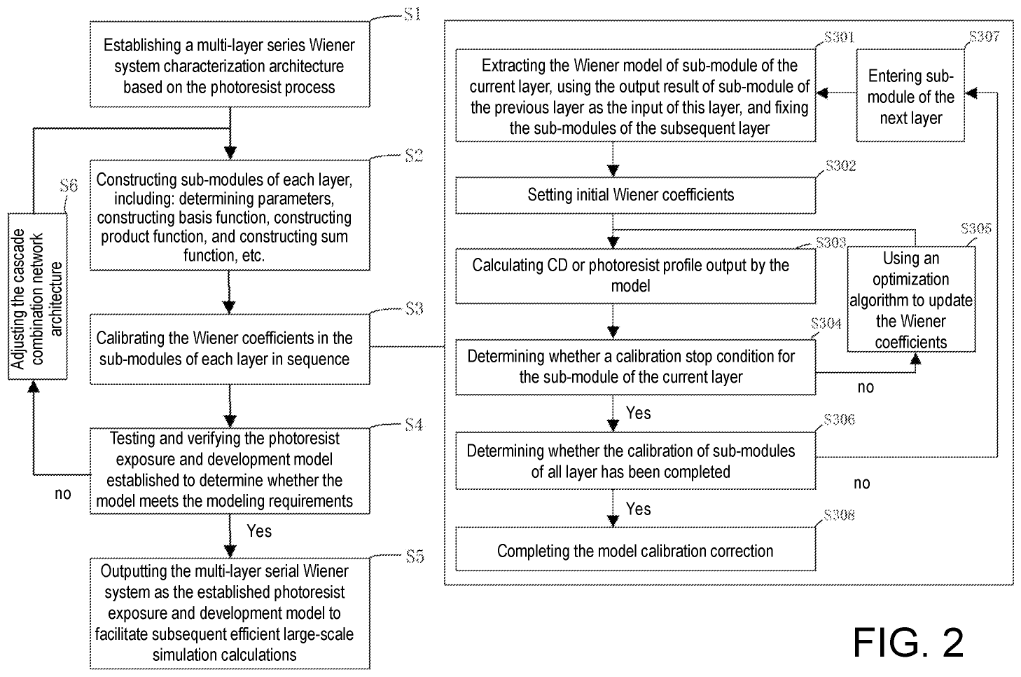

This embodiment takes the photoresist model during exposure and development as an example to illustrate the modeling and calibration method of the nonlinear system in computational lithography. The specific implementation steps are shown in FIG. 2.

Step S1: establishing an overall network architecture for multi-stage Wiener system characterization based on the photoresist exposure and development process.

Step S2: constructing specific Wiener modules for the sub-modules of each stage, which may be but is not limited to: second-order Wiener modules, linear Wiener modules and Wiener-Padé modules. The construction process is: determining the input and output of the sub-module of this stage, the form of the Wiener module of this stage, selecting and constructing the Wiener basis function; further constructing the product function for the second-order terms, and performing weighted summation for basis functions of different orders to construct sum functions; constructing the product functions and sum functions of the numerator and denominator respectively for Wiener-Padé terms, and further performing pointwise division to construct the Wiener-Padé module.

Step S3: calibrating the Wiener coefficients in the sub-modules of each stage in sequence according to the cascade sequence.

The photoresist model during exposure and development may be described by the Wiener model provided by the present disclosure. A three-dimensional spatial intensity distribution is used as input, multiple two-dimensional images are used as output, and photoresist profile structures of different depths or heights are generated through threshold setting. The photoresist exposure and development process is a typical nonlinear transformation process. Therefore, it is very important to use the three-dimensional intensity distribution inside the photoresist as input to construct the photoresist model. In this way, the photoresist model may be characterized as the Wiener nonlinear system which is described by a nonlinear functional, which converts the input signal of the three-dimensional intensity distribution into the output signal of the three-dimensional photoresist topography. In actual operation, the three-dimensional intensity distribution may be represented by a limited number of two-dimensional aerial images at different depths, and the photoresist profile images may be obtained by intersecting the three-dimensional topography with a set of planes of different heights. Mathematically, the profile at each specific height may be viewed as being generated by thresholding a continuous two-dimensional signal distribution, which may be generated by a Wiener nonlinear system that takes a two-dimensional aerial image as input. In this way, each photoresist profile of different heights is associated with the Wiener model, that is, the discretely sampled photoresist three-dimensional topography is related to the Wiener model vector.

The three-dimensional topography of the exposed and developed photoresist may be described by profile curves of different depths or selected points thereon, especially in edge conditions, for example, using profile edge graphics at the top, middle, and bottom of the photoresist. These profile curves or selected points may be obtained through real tape-out exposure results or simulated exposure results based on first principles. A set of photoresist profile curves at each depth may be regarded as an output of the Wiener nonlinear model. The input of the model is the same two-dimensional aerial image sample, and different threshold truncation is configured to obtain each set of photoresist profile at different depths, therefore these photoresist curves may be configured to calibrate the system. For example, the threshold may be set as the arithmetic mean or least square mean of the two-dimensional image intensities of a set of profile curves at a specific depth or selected points thereon. Alternatively, one may choose to set the threshold to minimize the photoresist edge placement error. Then, the calibrated Wiener nonlinear model may be configured to predict multiple sets of profile curves of resists at different depths, thus solving the problem of high efficiency and large computational load of full-chip simulation calculations in actual large-scale manufacturing. This Wiener model may accurately predict the three-dimensional photoresist topography, such as the top critical dimension (CD), bottom CD, sidewall slope, and even the barrel or needle-shaped cross-section of the photoresist structure.

Similarly, the Wiener nonlinear model may be configured to simulate the three-dimensional morphology of the photoresist on the silicon wafer surface during wet etching or plasma etching. The input to the Wiener model may be a set of profile curves describing the resist edge at different depths, and the output of each Wiener model may be a two-dimensional signal distribution that gives the edge or sidewall profiles of a photoresist three-dimensional structure at a specific focal depth after applying a threshold intercept.

Specifically, the following steps S301 to S308 are included:

Step S301: extracting the Wiener model of the sub-module of the current stage, using the output result of sub-module of the previous stage as the input of this stage, convolving with the Wiener kernel function and storing the model; in the meantime, fixing the sub-modules of the subsequent stage to be identity or simple linear operator.

Step S302: performing initial settings for the Wiener coefficients that need to be calibrated, such setting method may be but is not limited to randomly generating a set of non-zero calibration parameters that need to be calibrated.

Step S303: calculating the model output, obtaining the output result of the sub-module of the last stage, and obtaining the critical dimension (CD) or other photoresist profile data set of the current model simulation in combination with the photoresist threshold setting.

Step S304: comparing the simulation data calculated in step S303 with the reference data to determine whether a calibration stop condition for the sub-module of the current stage is met. The reference data preferably uses CD or other photoresist profile data obtained through actual exposure experiments. If the calibration stop condition for the sub-module of the current stage is not met, move to step S305; if the calibration stop condition is met, move to step S306.

Step S305: using an optimization algorithm to update the Wiener coefficients, wherein the optimization algorithm may adopt, but is not limited to, various second-order optimization solving algorithms.

Step S306: determining whether the calibration of sub-modules of all stages has been completed, if the calibration has not been completed, that is, the current stage is not the last stage, move to step S307; if the calibration has been completed, that is, the current stage is the last stage, move to step S308.

Step S307: entering the calibration process of the Wiener coefficient of sub-module of the next stage.

Step S308: completing the model calibration and outputting the Wiener coefficients at each stage.

Step S4: testing and verifying the photoresist model calibrated in step S3 to determine whether the model meets the modeling requirements. If the requirements are met, move to step S5; if the requirements are not met, move to step S6. The data sample for test verification may be a data sample different from the calibration. Preferably, the data sample may be obtained by using CD or other photoresist profile data obtained from actual photoresist exposure and development experiments.

Step S5: outputting the Wiener system as the established photoresist model to facilitate subsequent efficient large-scale simulation calculations.

Step S6: adjusting the cascade combination network architecture and performing the calibration and verification process of the new architecture. The method of adjusting the cascade combination architecture may be, but is not limited to: 1) adding one stage of cascade connection to expand the depth of the network; 2) internally adjusting one of the stages to a form two or more Wiener sub-modules connected in parallel; 3) adjusting an inner combination method within a certain stage, for example, when two second-order Wiener modules are added, the two modules may adopt two different sets of kernel functions, while the kernel function of one module is set to use a smaller Gaussian diffusion coefficient σ, and the other module uses a larger σ.

### Embodiment 2

This embodiment adopts a three-dimensional thick mask diffraction model as an example to illustrate the modeling and calibration method of calculating the nonlinear system.

In the vector lithography modeling process, the three-dimensional thick mask diffraction process may be described using the Wiener model provided by the present disclosure. The three-dimensional mask may be regarded as a stack of different material slices. Each material slice is determined by the two-dimensional distribution characteristics and physical parameters of the material. The two-dimensional distribution may be discrete or continuous; the physical parameters include but are not limited to dielectric constant, absorption coefficient, electron gas density, conductivity, etc. This collection of two-dimensional distributions serves as the input to the Wiener model, and the diffraction field serves as the output.

The functional relationship between the input signal and the output signal is normally nonlinear and may be represented by convolving the input signal with a set of preset Wiener kernels, and then calculating and weighting are carried out to perform summation on the nonlinear product of convolution results. The Wiener coefficients of the Wiener model may be calibrated by simulating diffraction using strict differential methods, which may be, but are not limited to, the finite element method (FEM) or the finite difference time domain (FDTD) method. Once calibrated, fast Fourier transform (FFT) is utilized, and the Wiener model may quickly predict the diffraction field of a large area three-dimensional thick mask.

Furthermore, when using the Wiener model to characterize the three-dimensional characteristics of the mask, the Wiener coefficient may be expressed as a function, for example, a low-order multivariable polynomial of a physical parameter, specifically, such as the spatial frequency of the illumination, the material of the mask, including material parameters and morphology parameters including layer thickness and dielectric constant.

In an optional example, for Wiener modeling of thick masks, different incident azimuth angles correspond to simple rotations of the kernel function, which can be described by using but not limited to Hermitian-Gaussian or Laguerre-Gaussian modes with a set of Wiener coefficients related to the azimuth angle.

It is easy for those skilled in the art to understand that the above descriptions are only preferred embodiments of the present disclosure and are not intended to limit the present disclosure. Any modifications, equivalent substitutions and improvements, etc., made within the spirit and principles of the present disclosure should all be included in the scope to be protected by the present disclosure.

What is claimed is:

1. A modeling method for a nonlinear system in computational lithography, comprising:
calculating a corresponding modeling module according to a kernel function group of each modeling module in a network architecture of a computational lithography system until all modeling modules are calculated, and obtaining an overall network model of the computational lithography system, wherein
the network architecture is composed of a plurality of identical or different stage structures, the stage structure is composed of a plurality of identical or different modeling modules, and the entire network architecture comprises at least one second-order Wiener module;
a number of stages of the network architecture, connection methods between different stages, a number and combination of the modeling modules in each stage of the stage structure, and the kernel function group of each of the modeling modules are all set according to characteristics of the nonlinear system.

2. The method according to claim 1, wherein for each of the second-order Wiener modules, performing eigen decomposition on the coefficient matrix of the second-order Wiener product function, an eigenmatrix and an original kernel function are merged, summed in advance and stored as a new kernel function, and eigenvalues are used as variable coefficients.

3. The method according to claim 1, wherein types of the modeling modules comprise: linear Wiener modules, second-order Wiener modules and Wiener-Padé modules; the combination of the modeling modules comprise: addition, subtraction or construction branches; the connection methods of the modeling modules comprise: cascade, parallel or mixed connection.

4. The method according to claim 3, wherein for each of the Wiener-Padé modules, product functions and sum functions of a numerator and a denominator are constructed respectively, and further constructed by point-by-point division.

5. The method according to claim 1, wherein a calculation of the new kernel function is specifically as follows:
(1) performing eigen decomposition on a coefficient matrix of a second-order term of a Wiener system to obtain an eigenvector matrix U;
(2) calculating a new Wiener kernel function G=U*K, wherein K represents an original Wiener kernel function.

6. The method according to claim 5, wherein a new Wiener kernel function is reduced in order to obtain a reduced second-order term T_{qua}=Σᵢλᵢ(I⊗Gᵢ)²; wherein λ is a new Wiener coefficient of the second-order term, a subscript i represents an i-th new Wiener kernel function, and I represents an input signal.

7. The method according to claim 1, wherein the method further comprises:
after performing parameter calibration of the overall network model, verifying the overall network model of the computational lithography system to determine whether the model meets modeling requirements; if the model meets the modeling requirements, output the overall network model; otherwise, adjust and remodel the network architecture.

8. The method according to claim 7, wherein the adjustment method is at least one of the following: 1) adding one stage of cascade connection to expand a depth of the network; 2) adjusting one of the stages to a form of two or more Wiener sub-modules connected in parallel; 3) adjusting an inner combination method of one of the stages.

9. The method according to claim 1, wherein the computational lithography system is a three-dimensional thick mask diffraction system or a photoresist reaction system during exposure and development.

10. The method according to claim 9, wherein if the system is the three-dimensional thick mask diffraction system, criterion for meeting the modeling requirements is: a difference between a diffraction light field output by the model and a reference diffraction light field is less than a preset value; if the system is the photoresist reaction system, the criterion for meeting the modeling requirements is: a difference between simulation critical dimensions of photoresist or a photoresist profile data output by the calibrated model and a reference data is less than a specified value or a preset value.

11. A calibration method for a nonlinear system in computational lithography, wherein calibration method comprises:
T1: receiving and calculating the overall network model of the lithography system, which is modeled using the method according to claim 1;
T2: receiving calibration data samples of the computational lithography system, wherein the calibration data sample comprises calculating an input data of a first stage of the lithography system and an actual output value of a sub-module of a last stage;
T3: extracting a Wiener model of a sub-module of the first-stage, convolving with the Wiener kernel function and storing the Wiener model; fixing sub-modules of a subsequent stage as an identity or a simple linear operator, and initializing a current stage to a second stage;
T4: extracting the Wiener model of a sub-module of a current stage, using an output result of a sub-module of a previous stage as an input of the stage, convolving with the Wiener kernel function and storing the model; fixing the sub-module of the subsequent stage to be the identity or the simple linear operator;
T5: initializing the Wiener coefficients that need to be calibrated;
T6: calculating the model output and obtaining an estimated output of the sub-module of the last stage;
T7: comparing the estimated output of the sub-module of the last stage with the actual output of the sub-module of the last stage to determine whether a calibration stop condition for the sub-module of the current stage is met, if the calibration stop condition is not met, move to step T8; if the calibration stop condition is met, move to step T9;
T8: optimizing and updating the Wiener coefficients;
T9: determining whether the calibration of the sub-modules of all stages has been completed; if not, that is, the current stage is not the last stage, move to step T10; if yes, move to step T11;
T10: updating the current stage to a sub-module of a next stage of according to a connection sequence and move to step T4;
T11: completing a model calibration and outputting the Wiener coefficients of each stage.

12. The method according to claim 11, wherein for a square operation in the second-order term after the order reduction, upsampling is first performed during calculation, and the square operation is performed afterwards;
wherein the upsampling comprises: performing fast Fourier transform on the input signal to be squared into a frequency domain; extending a value interval to at least twice an original interval for each side in a spatial frequency domain, filling in a continuation area with zeros, and then using an inverse Fourier transform to return to an original domain.

13. A modeling and calibration device for a nonlinear system in computational lithography, comprising: a processor and a memory;
wherein the memory is configured to store computer execution instructions;
the processor is configured to execute the computer execution instructions, so that the method according to claim 1 is executed.

14. A computer readable storage medium, wherein a computer program is stored in the computer readable storage medium, and when the computer program is executed by a processor, the steps of the method according to claim 1 are implemented.

15. The method according to claim 2, wherein the computational lithography system is a three-dimensional thick mask diffraction system or a photoresist reaction system.

16. The method according to claim 3, wherein the computational lithography system is a three-dimensional thick mask diffraction system or a photoresist reaction system.

17. The method according to claim 4, wherein the computational lithography system is a three-dimensional thick mask diffraction system or a photoresist reaction system.

18. The method according to claim 5, wherein the computational lithography system is a three-dimensional thick mask diffraction system or a photoresist reaction system.

19. The method according to claim 6, wherein the computational lithography system is a three-dimensional thick mask diffraction system or a photoresist reaction system.

20. The method according to claim 7, wherein the computational lithography system is a three-dimensional thick mask diffraction system or a photoresist reaction system.
